(19) United States
(12) Patent Application Publication
(10) Pub. No.: US 2026/0251509 A1
(43) Pub. Date: Aug. 27, 2026

(54) WAFER SURFACE TEMPERATURE MEASUREMENT METHOD AND APPARATUS

(71) Applicant: SHANGHAI GND ETECH CO., LTD., Shanghai (CN)

(72) Inventors: Zihuan XIA, Shanghai (CN); Ping ZHANG, Shanghai (CN)

(73) Assignee: SHANGHAI GND ETECH CO., LTD., Shanghai (CN)

(21) Appl. No.: 19/304,616

(22) Filed: Aug. 20, 2025

(30) Foreign Application Priority Data
Feb. 25, 2025 (CN) 202510207036.5

(51) Int. Cl. G01K 11/14; H01L 21/66; H01L 21/67

(52) U.S. Cl. CPC G01K 11/14; H10P 72/0602; H10P 74/203

(57) ABSTRACT

Wafer surface temperature measurement method relates to technical field of semiconductor manufacturing, comprises: calcining fluorescent indicator at different preset calcining temperatures, calibrating marked temperature of fluorescent indicator after being calcined at same calcining temperature for different time periods; heating wafer having fluorescent indicator arranged, fluorescent indicator is distributed at preset positions on wafer at interval; acquiring measured temperatures of fluorescent indicator on wafer; and obtaining heating temperatures and heating time periods of fluorescent indicator, according to calcining temperature to fluorescent indicator, marked temperatures of fluorescent indicator after being calcined for different time periods, and measured temperatures of fluorescent indicator on wafer, thereby obtaining heating temperatures and heating time periods of corresponding positions on wafer surface, Being able to obtain both heating temperatures on wafer surface and heating time periods of wafer at same time, obtaining real thermal power being absorbed by wafer surface.

### TECHNICAL FIELD

The present application relates to the technical field of semiconductor manufacturing, in particular to a wafer surface temperature measurement method and an apparatus.

### BACKGROUND

During a semiconductor manufacturing process, wafer temperature is a critical parameter, which directly affects both quality and stability of various fabrication processes on the wafer. Proper control of wafer temperature can enhance the performance and reliability of semiconductor devices while reducing failure rates and product costs. For example, non-uniform wafer temperature distribution may cause excessive thermal gradients during a manufacturing process, thereby compromising device quality and performance through effects. Therefore, in an actual semiconductor fabrication, measuring wafer surface temperature and maintaining uniform temperature distribution through process design and equipment parameter optimization are essential to ensure device consistency across an entire wafer.

In the prior art, it usually adopts two methods to measure the wafer temperature, a wired thermocouple wafer temperature measurement method (wired TC Wafer) and a wireless wafer temperature measurement method. The wired TC Wafer adopts at least one thermocouple (TC) as a temperature sensor, which is connected to a temperature collector or a host computer through a lead, it is possible to measure a temperature in a range of almost 1000 DEG C. The TC has a simple structure and a convenient operation as well as an easy installation. However, since the wired TC Wafer requires the lead being externally connected to an outside of a wafer processing chamber, it requires a vacuum feedthrough to be designed. Further, the TC can measure a single point only in a measurement space at any given moment, thus for the wafer, by measuring a surface temperature parameter of the wafer at only one certain moment, it is impossible to give a real thermal power (a combination effect of both time and temperature) being absorbed by the wafer surface. According to the wireless temperature measurement method, it integrates both an electronic temperature measurement chip and a wireless module onto a wafer, thus it is able to transmit a temperature signal to a temperature collector or a host computer in a mode of wireless transmission. However, it cannot measure high temperatures, also a service life thereof is much shorter than that of a wired alternatives.

### SUMMARY

An objective of the present application is providing a wafer surface temperature measurement method and an apparatus, so as to obtain both heating temperature and heating time period at a preset position on a wafer surface.

In order to achieve the objective stated above, a first aspect of a technical scheme adopted by the present application provides a wafer surface temperature measurement method, comprising:
Calcining a fluorescent indicator at a plurality of different preset temperatures, and calibrating a plurality of marked temperatures of the fluorescent indicator after being calcined at a same calcining temperature for a plurality of different time periods;
heating a wafer having the fluorescent indicator arranged, wherein the fluorescent indicator is distributed at a plurality of preset positions on the wafer at an interval;
acquiring a plurality of measured temperatures of the fluorescent indicator on the wafer; and
obtaining a plurality of heating temperatures and a plurality of heating time periods of the fluorescent indicator, according to a calcining temperature to the fluorescent indicator, the plurality of marked temperatures of the fluorescent indicator after being calcined for the plurality of different time periods, and the plurality of measured temperatures of the fluorescent indicator on the wafer, thereby obtaining a plurality of heating temperatures and a plurality of heating time periods of a plurality of corresponding positions on the wafer surface.

In an embodiment, the calcining the fluorescent indicator at the plurality of different preset temperatures, and calibrating the plurality of marked temperatures of the fluorescent indicator after being calcined at the same calcining temperature for the plurality of different time periods, wherein the plurality of different preset temperatures are increasing at a preset temperature interval, and the plurality of different time periods are increasing at a preset time interval.

In an embodiment, the heating the wafer having the fluorescent indicator arranged, wherein the fluorescent indicator is distributed at a plurality of preset positions on the wafer at an interval, and the plurality of preset positions are a plurality of indentations arranged at an interval formed on the surface of the wafer.

In an embodiment, the heating the wafer having the fluorescent indicator arranged, wherein the wafer is heated by a vapor chamber, a heating plate or a thermostatic bath.

In an embodiment, the fluorescent indicator is made of a fluorescent material.

A second aspect of the present application provides a wafer surface temperature measurement apparatus, comprising a wafer, a fluorescent indicator, a heating structure and a temperature measurement structure;
the wafer has a plurality of indentations arranged on a surface at an interval, applied to accommodating the fluorescent indicator, the temperature measurement structure is applied to obtaining a plurality of measured temperatures of the fluorescent indicator after the wafer is heated, so as to obtaining the plurality of heating temperatures and the plurality of heating time periods of the fluorescent indicator, according to the calcining temperature to the fluorescent indicator, the plurality of marked temperatures of the fluorescent indicator after being calcined for different time periods and the plurality of measured temperatures of the fluorescent indicator on the wafer, thereby obtaining the plurality of heating temperatures and the plurality of heating time periods of the plurality of corresponding positions on the wafer surface.

In an embodiment, the plurality of indentations are a plurality of blind holes uniformly arranged in a same surface of the wafer at an interval.

In an embodiment, the plurality of indentations are distributed on the surface of the wafer in an array; or the plurality of indentations are uniformly distributed at an interval along a circumferential direction according to a center of the wafer.

In an embodiment, the fluorescent indicator is KLa(MoO4)2+, Eu³⁺:La₂O₂S, Cr:YAG, Nd:Glass, Cr³⁺:LiSrAlF₆, Cr:Al₂O₃, Nd:YAG, Cr:BeAl₂O₃; or the fluorescent indicator is a fluorescent material doped with Nd³⁺, a fluorescent material doped with Tm³⁺, a fluorescent material doped with Er³⁺, or a fluorescent material doped with Cr³⁺.

In an embodiment, the plurality of indentations have a plurality of windows arranged, applied to observing a changing condition of the fluorescent indicator.

In an embodiment, the window is a quartz window, a sapphire window, a magnesia-alumina spinel window or an aluminum oxynitride window; and the window is bonded to the surface of the wafer.

In an embodiment, the window is parallel to the surface of the wafer, and the window is higher than the surface of the wafer or the window is on a same level of the surface of the wafer.

In an embodiment, an outer contour of an opening of the indentation is a circular, having a diameter of 1-10 mm;
or, the outer contour of the opening of the indentation is a rectangular, having a length or a width of 1-10 mm;
the fluorescent indicator has a filling thickness of 0.1-0.5 mm inside the indentation.

In an embodiment, the temperature measurement structure is a fluorescent optical fiber temperature measurement structure, comprising an optical fiber probe and a temperature measurement display platform, one end of the optical fiber probe is connected with the temperature measurement display platform, another end thereof is applied to acquiring an optical signal of the fluorescent indicator.

The wafer surface temperature measurement method provided by the present application comprises the following steps: calcining a fluorescent indicator at a plurality of different preset calcining temperatures, and calibrating a plurality of marked temperatures of the fluorescent indicator after being calcined at a same calcining temperature for a plurality of different time periods; heating a wafer having the fluorescent indicator arranged, wherein the fluorescent indicator is distributed at a plurality of preset positions on the wafer at an interval; acquiring a plurality of measured temperatures of the fluorescent indicator on the wafer; and obtaining a plurality of heating temperatures and a plurality of heating time periods of the fluorescent indicator, according to the calcining temperature to the fluorescent indicator, the plurality of marked temperatures of the fluorescent indicator after being calcined for different time periods, and the plurality of measured temperatures of the fluorescent indicator on the wafer, thereby obtaining a plurality of heating temperatures and a plurality of heating time periods of a plurality of corresponding positions on the wafer surface. The wafer surface temperature measurement method is able to obtain both the plurality of heating temperatures on the wafer surface and the plurality of heating time periods of the wafer at a same time, as well as obtaining a real thermal power being absorbed by the wafer surface.

The wafer surface temperature measurement apparatus provided by the present application comprises a wafer, a fluorescent indicator, and a temperature measurement structure; the surface of the wafer has a plurality of indentations arranged at an interval, applied to accommodating the fluorescent indicator, the temperature measurement structure is applied to obtaining a plurality of measured temperatures of the fluorescent indicator after the wafer is heated, so as to obtaining the plurality of heating temperatures and the plurality of heating time periods of the fluorescent indicator, according to the calcining temperature to the fluorescent indicator, the plurality of marked temperatures of the fluorescent indicator after being calcined for the plurality of different time periods and the plurality of measured temperatures of the fluorescent indicator on the wafer, thereby obtaining the plurality of heating temperatures and the plurality of heating time periods of the plurality of corresponding positions on the wafer surface. The wafer surface temperature measurement apparatus is able to obtain both the plurality of heating temperatures on the wafer surface and the plurality of heating time periods of the wafer at a same time, thereby obtaining a real thermal power being absorbed by the wafer surface, instead of requiring an electronic temperature measurement chip or a wireless module, thus a service life thereof is prolonged.

### BRIEF DESCRIPTION OF THE DRAWINGS

In order to more clearly illustrate the technical solutions in the embodiments of the present application, the accompanying drawings required to be used in the description of the embodiments or the prior art are briefly introduced below, and obviously, the drawings in the following description are merely a part of all the embodiments of the present application. For a person of ordinary skill in the art, other drawings may be obtained according to these drawings without creative efforts.

FIG. 1 illustrates a flowchart on a wafer surface temperature measurement method provided by an embodiment of the present application;

FIG. 2 illustrates a schematic structural diagram on a wafer surface temperature measurement apparatus according to an embodiment of the present application;

FIG. 3 illustrates a top view on a wafer and an indentation formed in the wafer of a wafer surface temperature measurement apparatus according to an embodiment of the present application;

FIG. 4 illustrates a schematic structural diagram on an indentation and a window formed on a wafer of a wafer surface temperature measurement apparatus according to an embodiment of the present application;

FIG. 5 illustrates a top view on a wafer and an indentation formed on the wafer of a wafer surface temperature measurement apparatus according to an embodiment of the present application;

Wherein: 1—wafer, 2—fluorescent indicator, 3—temperature measurement structure, 11—indentation, 12—window, 31—optical fiber, 32—temperature measurement display platform.

### DESCRIPTION OF THE EMBODIMENTS

To make the objective, technical solutions and advantages of the present application clearer, the technical solutions in the embodiments of the present application will be clearly and completely described below with reference to the accompanying drawings of the present application. Apparently, the embodiments described are some rather than all of the embodiments of the present application. All other embodiments obtained by those of ordinary skill in the art based on the embodiments of the present application without creative efforts shall fall within the scope of protection of the present application.

The technical or scientific terms used herein shall have the usual meanings understood by those of ordinary skill in the art to which the present application belongs, unless otherwise defined. The similar term such as “include or comprise” refers to that an element or item that appears before the term covers elements or items listed after the term and their equivalents, without excluding other elements or items. For example, a process, a method, a system, a product, or a device that includes a series of steps or units is not necessarily limited to those steps or units that are clearly listed, but may include other steps or units that are not expressly listed or inherent to these processes, methods, products, or devices.

It is noted that the terms “length”, “width”, “upper”, “lower”, “front”, “rear”, “left”, “right”, “vertical”, “horizontal”, “top”, “bottom”, “inner”, “outer” and more are used to facilitate describing the present application and simplify the description, rather than indicating or implying that the device or element referred to has to have a specific orientation and is constructed and operated in a specific orientation, and therefore cannot be understood as a limitation to the present application.

In addition, the terms “first” and “second” are used for descriptive purposes only and cannot be understood as indicating or implying relative importance or implicitly indicating the number of indicated technical features. Thus, the features defined with “first” and “second” may explicitly or implicitly include one or more of the features. It should be understood that the term “and/or” used in this specification is merely an association relationship for describing associated objects, indicating that there may be three relationships, for example, A and/or B may indicate that A exists alone, A and B exist at a same time, and B exists alone. In the description of the present disclosure, unless otherwise specified, “a plurality of” means two or more.

A wafer temperature measurement method in the prior art generally adopts a wired thermocouple wafer temperature measurement method (wired TC Wafer) and a wireless temperature measurement method. Comparing to the wired TC Wafer, the wireless temperature measurement method has an advantage that, it is able to perform a wireless temperature measurement, instead of having to shutdown a machine before opening a semiconductor process chamber, and it is possible to transfer a chip on line directly to a plurality of temperature measurement positions including a chuck, a furnace tube and more, so as to reduce maintenance time, thus a usage efficiency is improved. However, a disadvantage thereof is that, it is impossible to measure a high-temperature, in particular for 500 DEG C. or more, since there is no electronic chip being able to work normally in the high-temperature so far, also both service life and product life are much less than that of a wired product.

In the prior art, an existing high-temperature wireless measurement technology mainly comprises a temperature measurement method with an infrared pyrometer, a temperature measurement method with a temperature measuring cone, a temperature measurement method with a temperature measuring block, and a temperature measurement method with a molten metal indication. The temperature measurement method with the infrared pyrometer measures a surface temperature of an object according to a method of black body radiation, however, it requires to design a mounting position and an observation window on a chamber. Due to a fact that an infrared emissivity is different corresponding to a different material, thus it requires a calibration being carried out respectively. The temperature measurement method with the temperature measuring cone or the temperature measuring block is monitoring a heating temperature and a heating time period of a heating material being heated in a furnace through a temperature measuring block or a temperature measuring cone. The heating material is influenced not only by the temperature but also by a time period exposed under the temperature, and by the temperature measuring block or the temperature measuring cone, it is possible to measure an amount of energy transferred during a heating process, that is, a thermal power (a combination effect of both time and temperature). During a measurement, it is possible to obtain a heating time period and a temperature parameter in a table look-up mode after measuring shrinkage of the temperature measuring block in the heating process or a bending position of the temperature measuring cone. However, during a temperature measurement process, the temperature measurement method with the temperature measuring cone or the temperature measuring block has to use a temperature measuring cone or a temperature measuring block with a different composition ratio, to measure a temperature in a different range, before deducting a specific temperature parameter according to a size change of the temperature measuring block or a bending angle change of the temperature measuring cone. The temperature measurement method with the molten metal indication is possible to indicate a temperature parameter of a wafer plane. However, a melting point change of a metal indicator is controlled by changing a component of the metal indicator, thus the method requires deploying and calibrating the component of the metal indicator in each chamber in advance, occupying a large volume, and the metal indicator having a heavy weight. Based on the problems stated above, the present application provides a wafer surface temperature measurement method and an apparatus.

The following provides a further detailed explanation on the wafer surface temperature measurement method and the apparatus proposed by the present application, in conjunction with the accompanying drawings and specific embodiments.

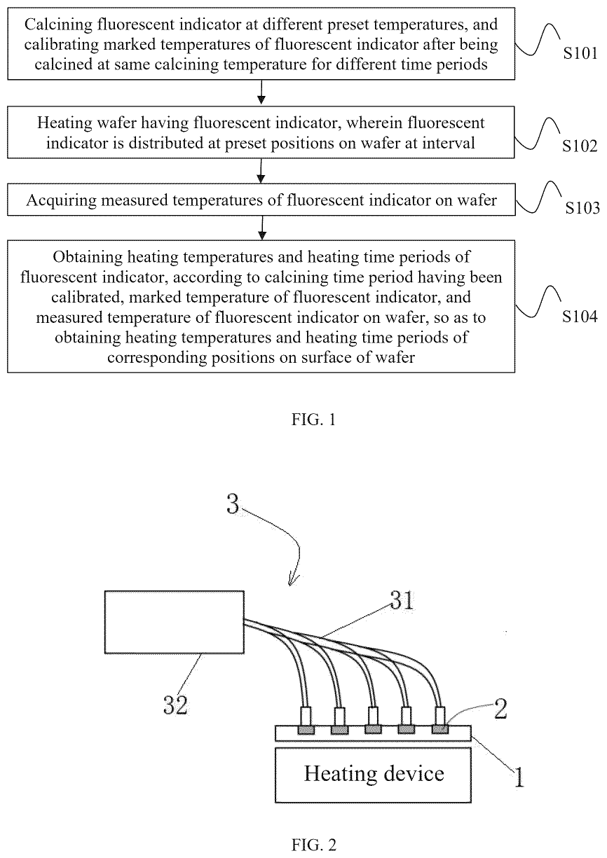

FIG. 1 illustrates a flowchart on a wafer surface temperature measurement method provided by an embodiment of the present application, referencing to FIG. 1, a first aspect of the present application provides a wafer surface temperature measurement method, comprising:
S101, calcining a fluorescent indicator at a plurality of different preset temperatures, and calibrating a plurality of marked temperatures of the fluorescent indicator after being calcined at a same calcining temperature for a plurality of different time periods;

Specifically, according to the present embodiment, the calcining a fluorescent indicator at a plurality of different preset temperatures, means, calcining the fluorescent indicator under a plurality of different temperature gradients, and recording a plurality of marked temperature values of the fluorescent indicator after a plurality of calcining periods at a specific calcining temperature. Table 1 shows a plurality of marked temperatures of a corresponding fluorescent indicator at a plurality of different calcining temperatures and after a plurality of different calcining time periods. In an embodiment, calcining the fluorescent indicator at a calcining temperature of 1000 DEG C. for 30 min, 60 min, 90 min, 120 min, 150 min, 160 min, and 180 min, before obtaining a plurality of measured temperatures a1, a2, a3, a4 and a5 of the fluorescent indicator at room temperature. Further calcining the fluorescent indicator respectively for 30 min, 60 min, 90 min, 120 min, 150 min, 160 min and 180 min at a plurality of temperatures including 1100 DEG C., 1150 DEG C., 1200 DEG C. and 1250 DEG C., before measuring and recording the plurality of measured temperatures of the fluorescent indicator at room temperature. Wherein the plurality of measured temperatures of the fluorescent indicator at the room temperature is achieved by means of a fluorescence optical fiber temperature measurement system.

TABLE 1

| Calcining temp. & time | 30 min | 60 min | 90 min | 120 min | 150 min | 160 min | 180 min |
|---|---|---|---|---|---|---|---|
| 1000 DEG C. | a1 | a2 | a3 | a4 | a5 | a6 | a7 |
| 1100 DEG C. | b1 | b2 | b3 | b4 | b5 | b6 | b7 |
| 1150 DEG C. | c1 | c2 | c3 | c4 | c5 | c6 | c7 |
| 1200 DEG C. | d1 | d2 | d3 | d4 | d5 | d6 | d7 |
| 1250 DEG C. | e1 | e2 | e3 | e4 | e5 | e6 | e7 |

In order to improve a calibration accuracy of the fluorescent indicator, in an embodiment, the temperatures a1, a2, a3, a4 and a5 are a plurality of average values obtained by calcining the fluorescent indicator at the temperature of 1000 DEG C. for 30 min, 60 min, 90 min, 120 min, 150 min and 180 min respectively and repeated for multiple times. For example, a1 is an average value of a plurality of groups of the fluorescent indicator after being calcined for 30 min at the temperature of 1000 DEG C.

The temperatures b1, b2, b3, b4 and b5 are a plurality of average values obtained by calcining the fluorescent indicator at the temperature of 1100 DEG C. for 30 min, 60 min, 90 min, 120 min, 150 min and 180 min respectively, and repeated for multiple times.

The temperatures c1, c2, c3, c4 and c5 are a plurality of average values obtained by calcining the fluorescent indicator at the temperature of 1150 DEG C. for 30 min, 60 min, 90 min, 120 min, 150 min and 180 min respectively, and repeated for multiple times.

The temperatures d1, d2, d3, d4 and d5 are a plurality of average values obtained by calcining the fluorescent indicator at the temperature of 1200 DEG C. for 30 min, 60 min, 90 min, 120 min, 150 min and 180 min respectively, and repeated for multiple times.

The temperatures e1, e2, e3, e4 and e5 are a plurality of average values obtained by calcining the fluorescent indicator at the temperature of 1250 DEG C. for 30 min, 60 min, 90 min, 120 min, 150 min and 180 min respectively, and repeated for multiple times.
S102, heating a wafer having the fluorescent indicator arranged, wherein the fluorescent indicator is distributed at a plurality of preset positions on the wafer at an interval;

Specifically, the fluorescent indicator is distributed at a plurality of preset positions on the wafer at an interval, as stated in the present embodiment, for example, the fluorescent indicator is distributed on a surface of the wafer in an array; or the fluorescent indicator is uniformly distributed at an interval along a circumferential direction according to a center of the wafer. The present embodiment distributes the fluorescent indicator to the plurality of preset positions of the wafer at an interval, and obtains the heating temperature and the heating time period at the preset position on the wafer through the plurality of measured temperatures of the fluorescent indicator at the preset position, before obtaining a temperature distribution on the surface of the wafer as a whole, so as to help an operator to know a temperature condition of the wafer comprehensively. In the present embodiment, it is possible to adopt a uniform temperature plate, a heating plate or a constant temperature groove to heat up the wafer. For example, in the present embodiment, the wafer has an indentation formed at the preset position on the surface, wherein the fluorescent indicator is located in the indentation.

In the present embodiment, the fluorescent indicator is distributed at a plurality of preset positions on the wafer at an interval, wherein the fluorescent indicator is a same indicator as the fluorescent indicator having been calibrated, however, the fluorescent indicator can not be reused in the calibration process.
S103, acquiring a plurality of measured temperatures of the fluorescent indicator on the wafer;

Specifically, after the wafer has been heated for a certain time period, it obtains the measured temperature of the fluorescent indicator on the wafer. According to the embodiment, it adopts an optical fiber probe to obtain the measured temperature of the fluorescent indicator on the wafer at the room temperature.
S104, obtaining a plurality of heating temperatures and a plurality of heating time periods of the fluorescent indicator, according to a calcining time period having been calibrated, the marked temperature of the fluorescent indicator, and the measured temperature of the fluorescent indicator on the wafer, so as to obtaining a plurality of heating temperatures and a plurality of heating time periods of a plurality of corresponding positions on the surface of the wafer.

Specifically, according to table 1 on the temperature conversion, it is possible to deduce the heating time period and the heating temperature of the fluorescent indicator in each indentation of the wafer from the measured temperature of the fluorescent indicator in the indentation formed on the surface of the wafer, before obtaining the plurality of heating temperatures and the plurality of heating time periods corresponding to the plurality of preset positions on the surface of the wafer.

Table 1 in the present embodiment provides a plurality of marked temperatures of the fluorescent indicator obtained after the fluorescent indicator has been respectively calcined for 30 min, 60 min, 90 min, 120 min, 150 min, 160 min and 180 min at 1000 DEG C., 1100 DEG C., 1150 DEG C., 1200 DEG C. and 1250 DEG C. Of course, a temperature gradient and an interval between two heating time periods can be further adjusted in a plurality of other calibration processes. In an embodiment, it starts from a temperature of 800 DEG C., the wafer with the fluorescent indicator is calcined after having been heated to a plurality of different preset temperatures, the plurality of different preset temperatures are increasing in an interval of 25 DEG C. while for a same preset temperature, the plurality of time periods for calcining are increased in an interval of 30 minutes.

According to the present embodiment, it is possible to obtain more calibration values by reducing an interval between the preset temperatures and reducing an interval between the preset time periods. According to the present embodiment, in a calibration process, when it is calcining at different temperatures, if two temperature values marked in the table 1 appear to be same, then it can be re-calibrated by replacing with a different type of fluorescent indicator.

In a Chemical Vapor Deposition (CVD) process, the uniformity and accuracy of the temperature have an important influence on a formation quality and a yield of a thin film coating. Thus during a CVD installation process, a calibration and test process, or a process of analyzing an abnormal cause, it is necessary to detect the temperature inside a chamber of a CVD equipment. In the prior art, the TC wafer temperature measurement system is commonly used for temperature detection in a CVD chamber. A principle thereof is that, by a special fabrication process, a thermocouple of a high-temperature-resistant sensor is embedded at a specific position on the wafer surface, so as to obtain a plurality of real temperature measurement values at a plurality of specific positions on the wafer and a temperature distribution on the wafer as a whole. However, the TC wafer temperature measurement system requires connecting to a wire outside the CVD chamber, which requires designing a vacuum feedthrough, and an operator has to open the chamber after stopping the machine. However, the TC can measure only one point in space and time, that is, for a wafer, it can only measure a temperature parameter at one specific moment on a surface of the wafer, instead of providing real heat power absorbed by the surface of the wafer. According to the wafer surface temperature measurement method stated in the present embodiment, it is possible to obtain the heating temperature and the heating time period of the fluorescent indicator according to the calcining time period having been calibrated by the fluorescent indicator, the marked temperature of the corresponding fluorescent indicator and the measured temperature of the fluorescent indicator on the wafer, so as to obtain the heating temperature and the heating time period of a corresponding position of the wafer. That is, the wafer surface temperature measurement method of the present embodiment is able to indicate the temperature on the surface of the wafer and the heating time period of the wafer simultaneously, and able to obtain the real thermal power absorbed by the wafer surface, so as to help an operator to know a temperature condition of the wafer comprehensively.

The wafer surface temperature measurement method provided by the present application comprises the following steps: calcining a fluorescent indicator at a plurality of different preset calcining temperatures, and calibrating the marked temperature of the fluorescent indicator after being calcined at a same calcining temperature for a plurality of different time periods; heating the wafer on which the fluorescent indicator is arranged, wherein the fluorescent indicator is distributed at a plurality of preset positions on the wafer at intervals; acquiring a plurality of measured temperatures of the fluorescent indicator on the wafer; and based on the calcining temperature of the fluorescent indicator, the plurality of marked temperatures of the fluorescent indicator after being calcined for different time periods and the plurality of measured temperatures of the fluorescent indicator on the wafer, it obtain a plurality of heating temperatures and a plurality of heating time periods of the fluorescent indicator thereby determining a plurality of heating temperatures and a plurality of heating time periods of a plurality of corresponding positions on the wafer surface. The wafer surface temperature measurement method is able to obtain both the plurality of heating temperatures on the wafer surface and the plurality of heating time periods of the wafer at a same time, as well as obtaining a real thermal power being absorbed by the wafer surface.

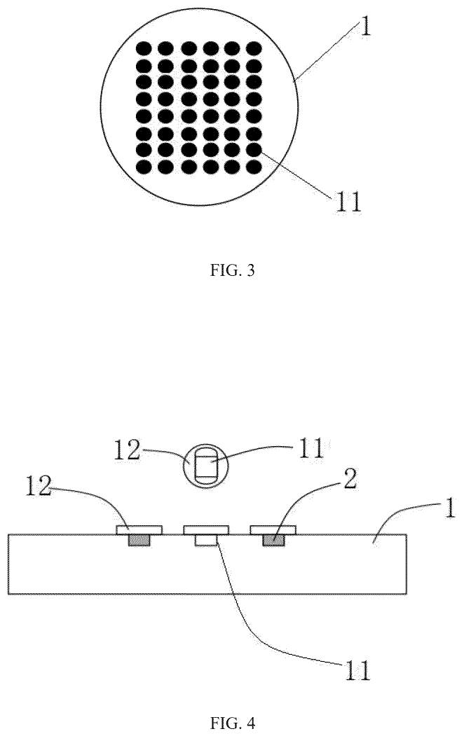

FIG. 2 illustrates a schematic structural diagram on a wafer surface temperature measurement apparatus according to an embodiment of the present application; FIG. 3 illustrates a top view on a wafer and an indentation formed in the wafer of a wafer surface temperature measurement apparatus according to an embodiment of the present application. Referring to FIG. 2 and FIG. 3, a second aspect of the present embodiment provides a wafer surface temperature measurement apparatus, comprising a wafer 1, a fluorescent indicator 2 and a temperature measurement structure 3.

The surface of the wafer 1 has a plurality of indentations 11 arranged at intervals, applied to accommodating the fluorescent indicator 2, the temperature measurement structure 3 is configured to obtain a plurality of measured temperatures of the fluorescent indicator 2 after the wafer 1 is heated, so as to obtain the plurality of heating temperatures and the plurality of heating time periods of the fluorescent indicator 2 based on the calcining temperature of the fluorescent indicator, the plurality of marked temperatures of the fluorescent indicator after being calcined for different time periods and the plurality of measured temperatures of the fluorescent indicator 2 on the wafer 1, thereby obtaining the plurality of heating temperatures and the plurality of heating time periods of the plurality of corresponding positions across the wafer 1.

The wafer surface temperature measurement apparatus of the present embodiment can be applied to a temperature detection in a reaction chamber of a CVD equipment, and the wafer surface temperature measurement apparatus obtains the heating temperature and the heating time period of the fluorescent indicator 2 based on the calcining time period of the fluorescent indicator calibrated in the wafer surface temperature measurement method described in the embodiments stated above, the marked temperature of the corresponding fluorescent indicator and the measured temperature of the fluorescent indicator 2 on the wafer 1. Thus, it can obtain the heating temperature and the heating time period of a corresponding position of the wafer 1. The heating temperature, the heating time period at a specific position of the wafer 1, and the temperature distribution across the wafer 1 can help an engineer to evaluate the stability of a CVD process, track a temperature variation, and adjust a process parameter, thereby ensuring consistent quality and performance of a CVD-processed product.

The present embodiment has no particular limitation on a size of the wafer 1, and the size of the wafer 1 can be determined in advance according to a size of the wafer 1 being processed by the CVD equipment. A surface of the wafer 1 has a plurality of indentations 11 arranged, and the plurality of indentations 11 are arranged at intervals, while the plurality of indentations 11 are configured to accommodate the fluorescent indicator 2. The present embodiment has no special limitation on an outline of the indentation 11 on the surface of the wafer 1. In the present embodiment, by forming a plurality of indentations 11 in a plurality of positions on the surface of the wafer 1 to accommodate the fluorescent indicator 2, the temperature on the wafer surface can be obtained by measuring the temperature of the fluorescent indicator 2.

The present embodiment has no particular limitation on a specific material of the fluorescent indicator 2. In an embodiment, the fluorescent indicator 2 is KLa(MoO4)2+, Eu³⁺:La₂O₂S, Cr:YAG, Nd:Glass, Cr³⁺:LiSrAlF₆, Cr:Al₂O₃, Nd:YAG, Cr:BeAl₂O₃; alternatively, it can be a fluorescent material doped with Nd³⁺, a fluorescent material doped with Tm³⁺, a fluorescent material doped with Er³⁺, or a fluorescent material doped with Cr³⁺.

The temperature measurement structure 3 in the present embodiment is applied to measuring the measured temperature of the fluorescent indicator 2 after the wafer 1 is heated. A specific structure of the temperature measurement structure 3 is not particularly limited in the present embodiment, as long as it is able to obtain the measured temperature of the fluorescent indicator 2 at the corresponding position after the wafer 1 is heated. In an embodiment, the temperature measurement structure 3 comprises an optical fiber probe 31 and a temperature measurement display platform 32, one end of the optical fiber probe 31 is connected with the temperature measurement display platform 32, another end of the optical fiber probe 31 is applied to acquiring an optical signal of the fluorescent indicator 2.

The wafer surface temperature measurement apparatus provided by the present embodiment comprises the wafer 1, the fluorescent indicator 2, and the temperature measurement structure 3; the wafer surface has a plurality of indentations arranged at intervals, which are applied to accommodating the fluorescent indicator 2; the temperature measurement structure 3 is applied to obtaining a plurality of measured temperatures of the fluorescent indicator 2 after the wafer 1 is heated, so as to obtain the plurality of heating temperatures and the plurality of heating time periods of the fluorescent indicator 2, according to the calcining temperature of the fluorescent indicator 2, the plurality of marked temperatures of the fluorescent indicator 2 after being calcined for different time periods and the plurality of measured temperatures of the fluorescent indicator 2 on the wafer 1, a host computer can obtain the plurality of heating temperatures and the plurality of heating time periods of the plurality of corresponding positions on the wafer surface. The wafer surface temperature measurement apparatus is able to obtain both the plurality of heating temperatures on the wafer surface and the plurality of heating time periods of the wafer at same time, as well as obtain a real thermal power being absorbed by the wafer surface. Further, the wafer surface temperature measurement apparatus requires no electronic temperature measurement chip or wireless module, and a service life thereof is prolonged.

In a specific embodiment, the plurality of indentations 11 are a plurality of blind holes arranged in a same surface of the wafer, and the plurality of blind holes are uniformly arranged at an interval. According to the embodiment, the indentations 11 are formed in the same surface of the wafer 1, eliminating the need for additional structural to the wafer 1, enabling a simplified fabrication process.

Preferably, the plurality of indentations 11 are distributed on the surface of the wafer 1 in an array; or the plurality of indentations 11 are uniformly distributed at an interval in a circumferential direction according to a center of the wafer 1. In an embodiment, with reference to FIG. 3, the plurality of indentations 11 are arranged in multiple rows and multiple columns, having an equal space between every two indentations 11. According to the embodiment, the plurality of indentations 11 are uniformly distributed on the wafer 1 at an interval, thus by obtaining the measured temperatures of the fluorescent indicator 2 in the plurality of indentations 11, it is equivalent obtaining a plurality of temperatures of a plurality of corresponding positions on the wafer 1, so that the temperature distribution on the surface of the wafer 1 in a whole will be obtained. After an analysis system obtains a plurality of temperatures of a plurality of corresponding positions on the wafer 1, it is possible to draw a temperature distribution diagram of the wafer 1 surface, and that helps an operator to know comprehensively a temperature condition on the wafer 1.

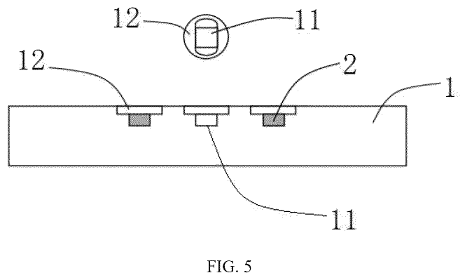

FIG. 4 illustrates a schematic structural diagram showing an indentation and a window formed on a wafer of a wafer surface temperature measurement apparatus according to an embodiment of the present application. FIG. 5 illustrates a top view of a wafer and an indentation formed in the wafer of a wafer surface temperature measurement apparatus according to an embodiment of the present application. Referencing to FIG. 4 and FIG. 5, further, the plurality of indentations 11 have a plurality of windows 12 arranged, applied to observing a changing condition of the fluorescent indicator 2. According to the present embodiment, by arranging the plurality of windows 12 on the plurality of indentations 11, it is possible to observe the fluorescence response of the fluorescent indicator 2 in the plurality of indentations 11 through the plurality of windows 12. In an embodiment, the fluorescent indicator 2 exhibits different fluorescence intensities under heated versus unheated conditions, allowing real-time observation of fluorescence phenomena of the fluorescent indicator 2 in the plurality of indentations 11 through the observation window 12.

Preferably, the window 12 is a quartz window, a sapphire window, a magnesia-alumina spinel window, or an aluminum oxynitride window, with a long service life. The plurality of windows 12 are bonded to the surface of the wafer 1, having a simple connection mode and easy to manufacture.

In an embodiment, the plurality of windows 12 are arranged parallel to the surface of the wafer 1, with their positions higher than or on a same level of the surface of the wafer 1. Shown as FIG. 4, when the windows 12 are positioned above the wafer 1 surface, the connection interface between the windows 12 and the wafer 1 is simpler compared to a flush-mounted configuration. Shown as FIG. 5, the plurality of windows 12 are on a same level of the surface of the wafer 1, maintaining the planar state of the wafer surface. When the window surface is aligned flush with the wafer surface, it facilitates adjustment of the total weight to match the original weight of wafer 1.

In the embodiment, it is possible to adjust a weight of the window 12, until a total system weight matches the weight of the original wafer 1. That is, keeping a weight of the plurality of windows 12 plus the fluorescent indicator 2 plus the wafer 1 matches the weight of the original wafer 1 having no indentation 11 arranged, so as to facilitate the robotic wafer handling.

In a specific embodiment, an outer contour of the indentation 11 opening is a circular, having a diameter of 1-10 mm. In a plurality of other embodiments, the outer contour of the opening of the indentation 11 is a rectangular, having a length or a width of 1-10 mm. Personnel in the art is able to predetermine the size of the indentation 11 in advance according to a size of the wafer 1.

In the embodiments stated above, a filling thickness of the fluorescent indicator 2 inside the indentation 11 is 0.1-0.5 mm. By keeping the filling thickness of the fluorescent indicator 2 inside the indentation 11 a specific amount, it ensures the accuracy of the temperature being obtained.

The embodiments stated above, wherein the temperature measurement structure 3 is a fluorescent optical fiber temperature measurement structure, comprising an optical fiber probe 31 and a temperature measurement display platform 32, wherein one end of the optical fiber probe 31 is connected with the temperature measurement display platform 32, another end thereof is applied to acquiring an optical signal of the fluorescent indicator 2. When the wafer surface temperature measurement apparatus of the present embodiment is performing a temperature measurement on a CVD machine, it only requires placing a wafer 1 having the fluorescent indicator 2 arranged into a chamber of the CVD machine, and after being heated in the chamber of the CVD machine for a certain period of time, the wafer 1 is taken out from the chamber of the CVD machine and placed in the room temperature, before measuring the fluorescent signal of the fluorescent indicator 2 in each of the plurality of indentations 11 in the wafer 1 through the optical fiber probe 31, the temperature measurement display platform 32 is then able to obtain a measured temperature of the fluorescent indicator 2 based on the fluorescent signal. Based on a calcining time period of the fluorescent indicator 2 having been calibrated according to the wafer surface temperature measurement method stated in the embodiment stated above, a plurality of marked temperatures of the fluorescent indicator 2 after having been calcined for different time periods, and the plurality of measured temperatures of the fluorescent indicator 2 on the wafer 1, both the plurality of heating temperatures and the plurality of heating time periods of the fluorescent indicator 2 on the wafer 1 are obtained, thereby both a plurality of heating temperatures and a plurality of heating time periods of a plurality of corresponding positions on the surface of the wafer 1 are obtained. A temperature measurement principle of the fluorescent optical fiber temperature measurement structure in the present embodiment is the prior art, and a temperature measurement principle of the fluorescent optical fiber temperature measurement structure is not further described in the present embodiment.

The wafer surface temperature measurement apparatus provided by the present application comprises a wafer 1, a fluorescent indicator 2, and a temperature measurement structure 3; the surface of the wafer 1 contains a plurality of indentations arranged at an interval, applied to accommodating the fluorescent indicator 2, the temperature measurement structure 3 is applied to obtaining a plurality of measured temperatures of the fluorescent indicator 2 after the wafer 1 is heated, so as to obtain the plurality of heating temperatures and the plurality of heating time periods of the fluorescent indicator 2, based on the calcining temperature to the fluorescent indicator 2, the plurality of marked temperatures of the fluorescent indicator 2 after being calcined for different time periods and the plurality of measured temperatures of the fluorescent indicator 2 on the wafer 1, thereby obtaining the plurality of heating temperatures and the plurality of heating time periods of the plurality of corresponding positions on the surface of the wafer 1. The wafer surface temperature measurement apparatus is able to obtain both the plurality of heating temperatures on the wafer surface and the plurality of heating time periods of the wafer 1 at a same time, thereby obtaining a real thermal power being absorbed by the wafer surface, instead of requiring an electronic temperature measurement chip or a wireless module, thus a service life thereof is prolonged.

In the description stated above, the description with reference to the terms “an embodiment,” “some embodiments,” “an example,” “a specific example,” etc. means that a particular feature, structure, material, or characteristic described in connection with the embodiment or example is included in at least one embodiment or example of the present invention. In the present specification, the schematic expressions of the above terms do not necessarily refer to a same embodiment or example. Furthermore, a plurality of particular features, structures, materials, or characteristics described may be combined together in any suitable manner in any one or more embodiments or examples. In addition, different embodiments or examples described in this specification and features of different embodiments or examples may be combined by a person skilled in the art without contradicting each other.

Although the embodiments of the present application have been described in detail above, it is apparent to those skilled in the art that various modifications and variations can be made to these embodiments. However, it is to be understood that such modifications and variations are within the scope and spirit of the application as described in the appended claims and embodiments. Furthermore, the present application described herein may have other embodiments and may be carried out or implemented in various ways.

What is claimed is:

1. A wafer surface temperature measurement method, comprising:
calcining a fluorescent indicator at a plurality of different preset temperatures, and calibrating a plurality of marked temperatures of the fluorescent indicator after being calcined at a same calcining temperature for a plurality of different time periods;
heating a wafer having the fluorescent indicator arranged, wherein the fluorescent indicator is distributed at a plurality of preset positions on the wafer at an interval;
acquiring a plurality of measured temperatures of the fluorescent indicator on the wafer; and
obtaining a plurality of heating temperatures and a plurality of heating time periods of the fluorescent indicator, according to a calcining temperature to the fluorescent indicator, the plurality of marked temperatures of the fluorescent indicator after being calcined for the plurality of different time periods, and the plurality of measured temperatures of the fluorescent indicator on the wafer, thereby obtaining a plurality of heating temperatures and a plurality of heating time periods of a plurality of corresponding positions on the wafer surface.

2. The temperature measurement method according to claim 1, wherein the plurality of different preset temperatures are increasing at a preset temperature interval, and the plurality of different time periods are increasing at a preset time interval.

3. The temperature measurement method according to claim 2, wherein the plurality of preset positions are a plurality of indentations arranged at an interval formed on the surface of the wafer.

4. The temperature measurement method according to claim 3, wherein, wherein the wafer is heated by a vapor chamber, a heating plate or a thermostatic bath.

5. A wafer surface temperature measurement apparatus according to claim 1, comprising a wafer, a fluorescent indicator, a heating structure and a temperature measurement structure;
the wafer has a plurality of indentations arranged on a surface at an interval, applied to accommodating the fluorescent indicator, the temperature measurement structure is applied to obtaining a plurality of measured temperatures of the fluorescent indicator after the wafer is heated, so as to obtaining the plurality of heating temperatures and the plurality of heating time periods of the fluorescent indicator, according to the calcining temperature to the fluorescent indicator, the plurality of marked temperatures of the fluorescent indicator after being calcined for different time periods and the plurality of measured temperatures of the fluorescent indicator on the wafer, thereby obtaining the plurality of heating temperatures and the plurality of heating time periods of the plurality of corresponding positions on the wafer surface.

6. The temperature measurement apparatus according to claim 5, wherein the plurality of indentations are a plurality of blind holes uniformly arranged in a same surface of the wafer at an interval.

7. The temperature measurement apparatus according to claim 6, wherein the plurality of indentations are distributed on the surface of the wafer in an array; or the plurality of indentations are uniformly distributed at an interval along a circumferential direction according to a center of the wafer.

8. The temperature measurement apparatus according to claim 5, wherein the fluorescent indicator is KLa(MoO4)2+, Eu³⁺:La₂O₂S, Cr:YAG, Nd:Glass, Cr³⁺:LiSrAlF₆, Cr:Al₂O₃, Nd:YAG, Cr:BeAl₂O₃; or the fluorescent indicator is a fluorescent material doped with Nd³⁺, a fluorescent material doped with Tm³⁺, a fluorescent material doped with Er³⁺, or a fluorescent material doped with Cr³⁺.

9. The temperature measurement apparatus according to claim 5, wherein the plurality of indentations have a plurality of windows arranged, applied to observing a changing condition of the fluorescent indicator.

10. The temperature measurement apparatus according to claim 9, wherein the window is a quartz window, a sapphire window, a magnesia-alumina spinel window or an aluminum oxynitride window; and the window is bonded to the surface of the wafer.

11. The temperature measurement apparatus according to claim 9, wherein the window is parallel to the surface of the wafer, and the window is higher than the surface of the wafer or the window is on a same level of the surface of the wafer.

12. The temperature measurement apparatus according to claim 5, wherein an outer contour of an opening of the indentation is a circular, having a diameter of 1-10 mm;
or, the outer contour of the opening of the indentation is a rectangular, having a length or a width of 1-10 mm;
the fluorescent indicator has a filling thickness of 0.1-0.5 mm inside the indentation.

13. The temperature measurement apparatus according to claim 5, wherein the temperature measurement structure is a fluorescent optical fiber temperature measurement structure, comprising an optical fiber probe and a temperature measurement display platform, one end of the optical fiber probe is connected with the temperature measurement display platform, another end thereof is applied to acquiring an optical signal of the fluorescent indicator.
